(19) United States
(12) Patent Application Publication
(10) Pub. No.: US 2011/0060955 A1
(43) Pub. Date: Mar. 10, 2011

(54) METHOD AND APPARATUS FOR PROVIDING FREQUENCY ERROR ESTIMATION

(76) Inventor: Jakob Ludvigsen, Hvidovre (DK)

(21) Appl. No.: 12/554,598

(22) Filed: Sep. 4, 2009

(51) Int. Cl. H04B 17/00; G06F 11/07; H03M 13/09; G06F 11/10

(52) U.S. Cl. 714/746; 455/67.11; 714/807; 714/E11.023; 714/E11.032

(57) ABSTRACT

An apparatus for providing frequency error estimation may include at least one processor and at least one memory including computer program code. The at least one memory and the computer program code may be configured, with the processor, to cause the apparatus to perform at least receiving, at a receiving station, data descriptive of a received signal provided from a transmitting station, receiving confirmation data descriptive of a signal transmitted by the transmitting station corresponding to the received signal, and performing an error characteristic determination associated with operation of the receiving station. The error characteristic may define a probabilistic value of the error characteristic given the received signal and the corresponding confirmation data. A corresponding method and computer program product are also provided.

### TECHNOLOGICAL FIELD

Embodiments of the present invention relate generally to communication technology and, more particularly, relate to an apparatus, method and a computer program product for providing frequency error estimation.

### BACKGROUND

The modern communications era has brought about a tremendous expansion of wireline and wireless networks. Computer networks, television networks, and telephony networks are experiencing an unprecedented technological expansion, fueled by consumer demand. Wireless and mobile networking technologies have addressed related consumer demands, while providing more flexibility and immediacy of information transfer.

Current and future networking technologies continue to facilitate ease of information transfer and convenience to users. In order to provide easier or faster information transfer and convenience, telecommunication industry service providers are developing improvements to existing networks. For example, the evolved universal mobile telecommunications system (UMTS) terrestrial radio access networks (UTRAN and E-UTRAN), WiMAX (worldwide interoperability for microwave access), HSPA (high speed packet access), WLAN (wireless local area network), the GERAN (GSM (global system for mobile communications)/EDGE (enhanced data rates for GSM evolution) radio access network) system, WCDMA (wideband code division multiple access) and other access mechanisms are currently being developed. The E-UTRAN, which is also known as Long Term Evolution (LTE) or 3.9G, is aimed at upgrading prior technologies by improving efficiency, lowering costs, improving services, making use of new spectrum opportunities, and providing better integration with other open standards. These and many other communication networks, employ base stations or access points that are connected to a network in order to wirelessly communicate with wireless communication devices that may be distributed throughout a coverage area of a given base station or access point.

The wireless communication networks described above, and others like them, are generally aimed at providing wireless communication to mobile users. Some of the improvements made in connection with some or all of the above networks are aimed at providing ever higher data rates to end users with reduced error rates while using potentially hostile propagation channels. In order to achieve these aims, effort is sometimes expended in order to compensate for frequency changes in uplink and downlink directions. The frequency changes may be experienced for a number of reasons. For example, imprecise crystals and the effects of temperature variations on crystals can impact the transmitted frequency of a device such as a mobile terminal. Additionally, changes in the velocity at which a user of the mobile terminal is traveling can impact the relative received and transmitted frequencies of the mobile terminal over time.

Current mechanisms for providing frequency estimation used for compensating for frequency changes often employ burst level reception techniques and change the frequency received based on the frequency estimate of one burst or more averaged bursts as either a blind detection or a semi-blind detection. However, these mechanisms may not provide desirable levels of precision and/or may require relatively large samples of data in order to function.

Accordingly, it may be desirable to provide alternative mechanisms for providing frequency estimation.

### BRIEF SUMMARY OF EXEMPLARY EMBODIMENTS

A method and apparatus are therefore provided that may enable the provision of improved precision in relation to conducting frequency estimation. Moreover, some embodiments of the present invention may provide a non-blind detection algorithm for performing frequency error estimation with relatively good precision. After frequency error estimation is accomplished, some embodiments may further provide for the implementation of frequency error compensation using the information obtained during frequency error estimation.

In one exemplary embodiment, a method of providing frequency error compensation is provided. The method may include receiving, at a receiving station, data descriptive of a received signal provided from a transmitting station, receiving confirmation data descriptive of a signal transmitted by the transmitting station corresponding to the received signal, and performing an error characteristic determination associated with operation of the receiving station. The error characteristic may define a probabilistic value of the error characteristic given the received signal and the corresponding confirmation data.

In another exemplary embodiment, a computer program product for providing frequency error compensation is provided. The computer program product may include at least one computer-readable storage medium having computer-executable program code instructions stored therein. The computer-executable program code instructions may include program code instructions for receiving, at a receiving station, data descriptive of a received signal provided from a transmitting station, receiving confirmation data descriptive of a signal transmitted by the transmitting station corresponding to the received signal, and performing an error characteristic determination associated with operation of the receiving station. The error characteristic may define a probabilistic value of the error characteristic given the received signal and the corresponding confirmation data.

In another exemplary embodiment, an apparatus for providing frequency error compensation is provided. The apparatus may include at least one processor and at least one memory including computer program code. The at least one memory and the computer program code may be configured, with the processor, to cause the apparatus to perform at least receiving, at a receiving station, data descriptive of a received signal provided from a transmitting station, receiving confirmation data descriptive of a signal transmitted by the transmitting station corresponding to the received signal, and performing an error characteristic determination associated with operation of the receiving station. The error characteristic may define a probabilistic value of the error characteristic given the received signal and the corresponding confirmation data.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates one example of a communication system according to an exemplary embodiment of the present invention;

FIG. 2 illustrates a schematic block diagram of an apparatus for providing frequency error compensation according to an exemplary embodiment of the present invention; and

FIG. 3 illustrates a flowchart of a method of providing frequency error estimation in accordance with an exemplary embodiment of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements. Like reference numerals refer to like elements throughout. As used herein, the terms “data,” “content,” “information” and similar terms may be used interchangeably to refer to data capable of being transmitted, received and/or stored in accordance with embodiments of the present invention. Moreover, the term “exemplary”, as used herein, is not provided to convey any qualitative assessment, but instead merely to convey an illustration of an example. Thus, use of any such terms should not be taken to limit the spirit and scope of embodiments of the present invention.

Additionally, as used herein, the term ‘circuitry’ refers to (a) hardware-only circuit implementations (e.g., implementations in analog circuitry and/or digital circuitry); (b) combinations of circuits and computer program product(s) comprising software and/or firmware instructions stored on one or more computer readable memories that work together to cause an apparatus to perform one or more functions described herein; and (c) circuits, such as, for example, a microprocessor(s) or a portion of a microprocessor(s), that require software or firmware for operation even if the software or firmware is not physically present. This definition of ‘circuitry’ applies to all uses of this term herein, including in any claims. As a further example, as used herein, the term ‘circuitry’ also includes an implementation comprising one or more processors and/or portion(s) thereof and accompanying software and/or firmware. As another example, the term ‘circuitry’ as used herein also includes, for example, a baseband integrated circuit or applications processor integrated circuit for a mobile phone or a similar integrated circuit in a server, a cellular network device, other network device, and/or other computing device.

As defined herein a “computer-readable storage medium,” which refers to a physical storage medium (e.g., volatile or non-volatile memory device), can be differentiated from a “computer-readable transmission medium,” which refers to an electromagnetic signal.

Some embodiments of the present invention may provide a mechanism by which improvements may be experienced in relation to providing improved precision in relation to frequency estimation for use in frequency error compensation. In this regard, for example, a non-blind frequency estimation algorithm is described herein that may be employed for providing frequency error compensation.

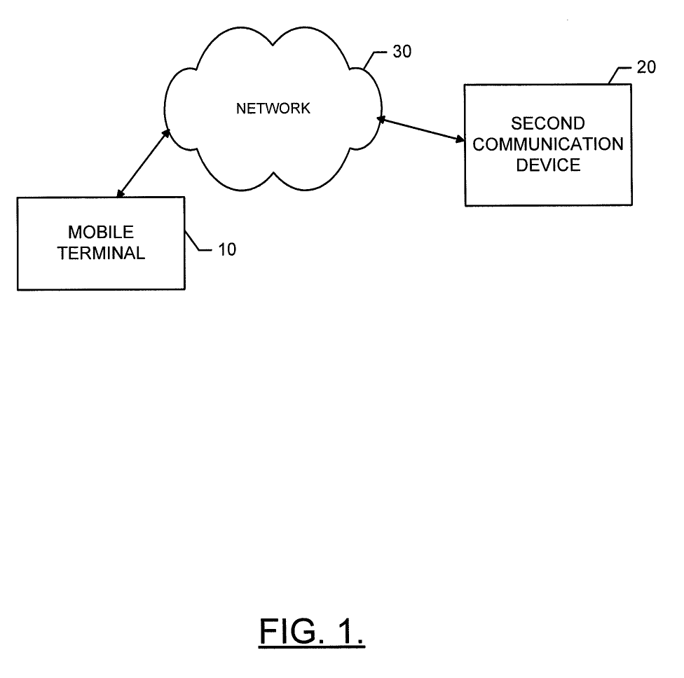

FIG. 1 illustrates a generic system diagram in which a device such as a mobile terminal 10, which may benefit from embodiments of the present invention, is shown in an exemplary communication environment. In this regard, the mobile terminal 10 may be configured to include an apparatus for providing frequency error compensation and/or frequency estimation in accordance with an exemplary embodiment. As shown in FIG. 1, an embodiment of a system in accordance with an example embodiment of the present invention may include a first communication device (e.g., mobile terminal 10) and a second communication device 20 capable of communication with each other. In an exemplary embodiment, the mobile terminal 10 and the second communication device 20 may be in communication with each other via a network 30. In some cases, embodiments of the present invention may further include one or more network devices with which the mobile terminal 10 and/or the second communication device 20 may communicate to provide, request and/or receive information. The network devices may include, for example, one or more servers, base stations, access points, gateways, communication controllers or other computers configured to perform various functions. In some cases, embodiments of the present invention may also or alternatively be practiced on one or more of the network devices and/or the communication devices that communicate with each other and/or the network devices.

It should be noted that although FIG. 1 shows a communication environment that may support, in some embodiments, communication between the mobile terminal 10 and the second communication device 20 via the network, other embodiments may also be practiced in the context of communications provided via a direct communication link between the mobile terminal 10 and the second communication device 20. Moreover, embodiments of the present invention may also be practiced without any second communication device. In other words, embodiments of the present invention may also be practiced in situations in which the mobile terminal 10 is communicating directly with one or more network devices (e.g., for downloading content or executing functionality associated with an application executed in a client/server environment between the mobile terminal 10 and a device or devices of the network 30).

The network 30, if employed, may include a collection of various different nodes, devices or functions that may be in communication with each other via corresponding wired and/or wireless interfaces. As such, the illustration of FIG. 1 should be understood to be an example of a broad view of certain elements of the system and not an all inclusive or detailed view of the system or the network 30. One or more communication terminals such as the mobile terminal 10 and the second communication device 20 may be in communication with each other via the network 30 or via device-to-device (D2D) communication and each may include an antenna or antennas for transmitting signals to and for receiving signals from a base site, which could be, for example a base station that is a part of one or more cellular or mobile networks or an access point that may be coupled to a data network, such as a local area network (LAN), a metropolitan area network (MAN), and/or a wide area network (WAN), such as the Internet. In turn, other devices such as processing elements (e.g., personal computers, server computers or the like) may be coupled to the mobile terminal 10 and/or the second communication device 20 via the network 30. By directly or indirectly connecting the mobile terminal 10 and/or the second communication device 20 and other devices to the network 30 or to each other, the mobile terminal 10 and/or the second communication device 20 may be enabled to communicate with the other devices or each other, for example, according to numerous communication protocols including Hypertext Transfer Protocol (HTTP) and/or the like, to thereby carry out various communication or other functions of the mobile terminal 10 and/or the second communication device 20, respectively.

Furthermore, although not specifically shown in FIG. 1, the mobile terminal 10 and the second communication device 20 may communicate in accordance with, for example, radio frequency (RF), Bluetooth (BT), Infrared (IR) or any of a number of different wireline or wireless communication techniques, including LAN, wireless LAN (WLAN), Worldwide Interoperability for Microwave Access (WiMAX), WiFi, ultra-wide band (UWB), Wibree techniques and/or the like. As such, the mobile terminal 10 and the second communication device 20 may be enabled to communicate with the network 30 and each other by any of numerous different access mechanisms. For example, mobile access mechanisms such as wideband code division multiple access (W-CDMA), CDMA2000, global system for mobile communications (GSM), LTE, general packet radio service (GPRS) and/or the like may be supported as well as wireless access mechanisms such as WLAN, WiMAX, and/or the like and fixed access mechanisms such as digital subscriber line (DSL), cable modems, Ethernet and/or the like.

In some example embodiments, the first communication device (e.g., the mobile terminal 10) may be a mobile communication device such as, for example, a personal digital assistant (PDA), wireless telephone, mobile computing device, camera, video recorder, audio/video player, positioning device (e.g., a global positioning system (GPS) device), game device, television device, radio device, or various other like devices or combinations thereof. The second communication device 20 may also be a mobile device such as those listed above or other mobile or embedded devices, but could also be a fixed communication device in some instances. As such, the mobile terminal 10, network device and/or the second communication device 20 may include, for example, processing circuitry that may include a processor and memory for storing instructions that are executable by the processor in order to cause the mobile terminal 10, network device and/or the second communication device 20, respectively, to perform corresponding operations that are defined by the instructions. In some cases, the processor of the mobile terminal 10, network device and/or the second communication device 20 may be embodied as, include, or otherwise control processing hardware such as one or more application specific integrated circuits (ASICs), microcontroller units (MCUs), or digital signal processors (DSPs) that are configured to provide a corresponding specific functionality.

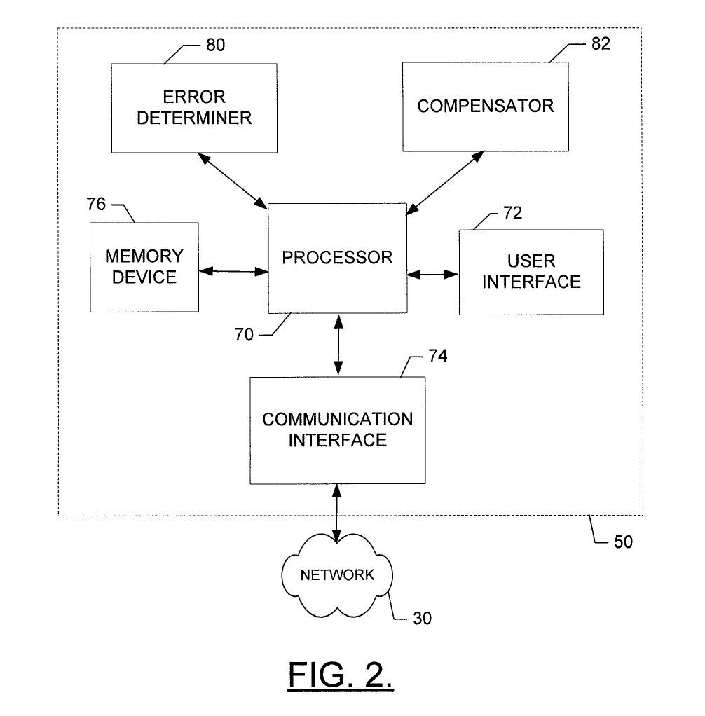

In an exemplary embodiment, the mobile terminal 10 may be configured to include or otherwise employ an apparatus according to an exemplary embodiment of the present invention. FIG. 2 illustrates a schematic block diagram of an apparatus for providing frequency estimation for frequency error correction according to an exemplary embodiment of the present invention. An exemplary embodiment of the invention will now be described with reference to FIG. 2, in which certain elements of an apparatus 50 for providing frequency estimation for frequency error correction are displayed. The apparatus 50 of FIG. 2 may be employed, for example, on a communication device (e.g., the mobile terminal 10) or a variety of other devices, such as, for example, any of the network or other devices listed above. However, it should be noted that the components, devices or elements described below may not be mandatory and thus some may be omitted in certain embodiments. Additionally, some embodiments may include further components, devices or elements beyond those shown and described herein.

Referring now to FIG. 2, the apparatus 50 may include or otherwise be in communication with a processor 70, a user interface 72, a communication interface 74 and a memory device 76. The memory device 76 may include, for example, one or more volatile and/or non-volatile memories. In other words, for example, the memory device 76 may be an electronic storage device (e.g., a computer readable storage medium) comprising gates configured to store data (e.g., bits) that may be retrievable by a machine (e.g., a computing device). The memory device 76 may be configured to store information, data, applications, instructions or the like for enabling the apparatus to carry out various functions in accordance with exemplary embodiments of the present invention. For example, the memory device 76 could be configured to buffer input data for processing by the processor 70. Additionally or alternatively, the memory device 76 could be configured to store instructions for execution by the processor 70.

The processor 70 may be embodied in a number of different ways. For example, the processor 70 may be embodied as one or more of various processing means such as a coprocessor, a microprocessor, a controller, a digital signal processor (DSP), a processing element with or without an accompanying DSP, or various other processing devices including integrated circuits such as, for example, an ASIC (application specific integrated circuit), an FPGA (field programmable gate array), a microcontroller unit (MCU), a hardware accelerator, a special-purpose computer chip, or the like. In an exemplary embodiment, the processor 70 may be configured to execute instructions stored in the memory device 76 or otherwise accessible to the processor 70. Alternatively or additionally, the processor 70 may be configured to execute hard coded functionality. As such, whether configured by hardware or software methods, or by a combination thereof, the processor 70 may represent an entity (e.g., physically embodied in circuitry) capable of performing operations according to embodiments of the present invention while configured accordingly. Thus, for example, when the processor 70 is embodied as an ASIC, FPGA or the like, the processor 70 may be specifically configured hardware for conducting the operations described herein. Alternatively, as another example, when the processor 70 is embodied as an executor of software instructions, the instructions may specifically configure the processor 70 to perform the algorithms and/or operations described herein when the instructions are executed. However, in some cases, the processor 70 may be a processor of a specific device (e.g., a mobile terminal or network device) adapted for employing embodiments of the present invention by further configuration of the processor 70 by instructions for performing the algorithms and/or operations described herein. The processor 70 may include, among other things, a clock, an arithmetic logic unit (ALU) and logic gates configured to support operation of the processor 70.

Meanwhile, the communication interface 74 may be any means such as a device or circuitry embodied in either hardware, software, or a combination of hardware and software that is configured to receive and/or transmit data from/to a network and/or any other device or module in communication with the apparatus. In this regard, the communication interface 74 may include, for example, an antenna (or multiple antennas) and supporting hardware and/or software for enabling communications with a wireless communication network. In some environments, the communication interface 74 may alternatively or also support wired communication. As such, for example, the communication interface 74 may include a communication modem and/or other hardware/software for supporting communication via cable, digital subscriber line (DSL), universal serial bus (USB) or other mechanisms.

The user interface 72 may be in communication with the processor 70 to receive an indication of a user input at the user interface 72 and/or to provide an audible, visual, mechanical or other output to the user. As such, the user interface 72 may include, for example, a keyboard, a mouse, a joystick, a display, a touch screen, soft keys, a microphone, a speaker, or other input/output mechanisms. In an exemplary embodiment in which the apparatus is embodied as a server or some other network devices, the user interface 72 may be limited, or eliminated. However, in an embodiment in which the apparatus is embodied as a communication device (e.g., the mobile terminal 10), the user interface 72 may include, among other devices or elements, any or all of a speaker, a microphone, a display, and a keyboard or the like. In this regard, for example, the processor 70 may comprise user interface circuitry configured to control at least some functions of one or more elements of the user interface, such as, for example, a speaker, ringer, microphone, display, and/or the like. The processor 70 and/or user interface circuitry comprising the processor 70 may be configured to control one or more functions of one or more elements of the user interface through computer program instructions (e.g., software and/or firmware) stored on a memory accessible to the processor 70 (e.g., memory device 76, and/or the like).

In an exemplary embodiment, the processor 70 may be embodied as, include or otherwise control an error determiner 80 and a compensator 82. However, in an exemplary embodiment, the error determiner 80 and the compensator 82 may be embodied at a protocol stack and thus, may be located within the communication interface 74. The error determiner 80 and the compensator 82 may each be any means such as a device or circuitry operating in accordance with software or otherwise embodied in hardware or a combination of hardware and software (e.g., processor 70 operating under software control, the processor 70 embodied as an ASIC or FPGA specifically configured to perform the operations described herein, or a combination thereof) thereby configuring the device or circuitry to perform the corresponding functions of the error determiner 80 and the compensator 82, respectively, as described herein. Thus, in examples in which software is employed, a device or circuitry (e.g., the processor 70 in one example) executing the software forms the structure associated with such means.

The error determiner 80 may be configured to receive data descriptive of a received signal provided from a transmitting station and receiving confirmation data descriptive of a signal transmitted by the transmitting station corresponding to the received signal in order to enable the error determiner to perform an error characteristic estimation associated with operation of the receiving station. The error characteristic may define a probabilistic value of the error characteristic given the received signal and the corresponding confirmation data. In an exemplary embodiment, the error characteristic may be frequency error caused by imprecise crystals, temperature changes and/or velocity changes as described above. As such, the error determiner 80 may enable the apparatus 50 (e.g., mobile terminal 10) to estimate frequency error for the signal it is transmitting. In other words, the error determiner may enable determination of an error characteristic that defines a probable frequency error for a given received signal when having knowledge of the signal that was sent corresponding to the received signal.

In an exemplary embodiment, the error determiner 80 may be configured to execute an algorithm for determining a probabilistic value of a frequency error of the receiving station given the received signal and the corresponding confirmation data. In one example, the error determiner 80 is configured to determine a maximum likelihood solution for the equation P(F|R, S), where F is the frequency error, R is the received signal (or data indicative of the received signal) and S is the transmitted signal (or data indicative of the transmitted signal). In the example above, R may be defined as R=H*S·e^{-jft}+Noise where H is representative of the propagation channel that has to be estimated and the Noise is unknown. Thus, while earlier algorithms have estimated P(F|R) (estimating frequency error only based on the data received) in a blind detection, embodiments of the present invention may provide for error estimation in a non-blind detection. Moreover, it should be appreciated that, while a specific algorithm is described above, the algorithm described is not necessarily the only algorithm that may be practiced in connection with employment of exemplary embodiments of the present invention. As such, alternative algorithms configured to provide a determination of a probabilistic value of a frequency error of the receiving station given the received signal and the corresponding confirmation data may also be practiced in some example cases.

The confirmation data may be provided by any of a number of feedback mechanisms. In this regard, for example, some embodiments may employ a cyclic redundancy check (CRC) in the course of operation, and the CRC may provide an indication (e.g., via a hash function or other mechanism) of the data transmitted. The CRC may indicate to the receiving station (e.g., the mobile terminal 10) whether the preceding communication blocks have been decoded correctly. As such, the CRC may provide the bitpattern of the transmitted signal from which S may be determined. Knowing the bitpattern transmitted may enable the frequency estimation algorithm discussed above to provide improved precision in relation to frequency estimation.

Although, the embodiment described above applies to an example in which the error characteristic is frequency error, other differential values associated with other operational characteristics of the mobile terminal could also be determined in this manner. For example, the error determiner 80 could alternatively be used to determine timing differences. Thus, for example, the error determiner 80 may be configured to determine a probabilistic value of a timing difference of the receiving station given the received signal and the corresponding confirmation data.

Regardless of the value of the error characteristic determined and the particular characteristic (e.g., a frequency error or timing difference) that the error characteristic represents, some embodiments may utilize the determined error characteristic in order to adjust an operational characteristic of the receiving station to compensate for the error characteristic. In an exemplary embodiment, the compensator 82 may be configured to perform such operational characteristic adjustments. As such, for example, the compensator 82 may be configured to modify the operating frequency of the apparatus 50 in order to compensate for the frequency error that may be determined by the error determiner 80 as described above.

Thus, according to an exemplary embodiment, an apparatus for providing frequency error estimation is provided. By exploiting information provided to confirm decoding of a received message (e.g., CRC checks), embodiments of the present invention may enable non-blind detection for frequency error estimation. The frequency error estimated may then be utilized to perform frequency error compensation. An algorithm for performing frequency error estimation for use in frequency error compensation according to an exemplary embodiment may provide a relatively precise estimate of frequency error within a relatively short time or with a relatively small data sample set. Thus, for example, increased accuracy may be provided in idle mode operation or instances where a handover has occurred and it is desirable to perform frequency error compensation with a relatively small number of samples.

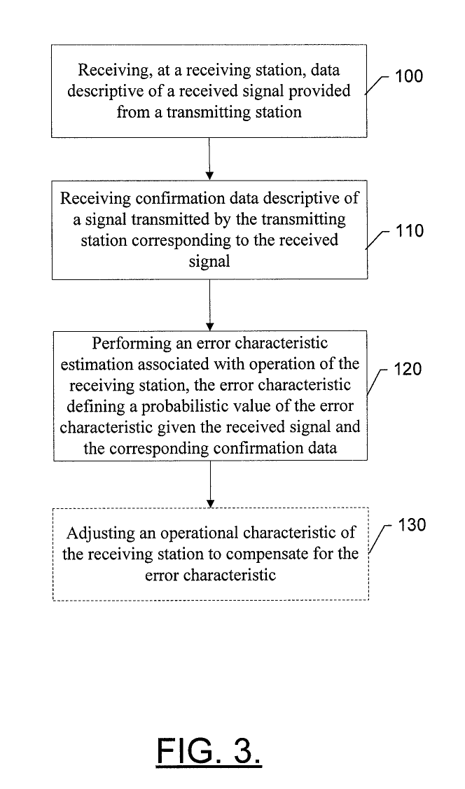

FIG. 3 is a flowchart of a system, method and program product according to exemplary embodiments of the invention. It will be understood that each block or step of the flowchart, and combinations of blocks in the flowchart, may be implemented by various means, such as hardware, firmware, processor, circuitry and/or other device associated with execution of software including one or more computer program instructions. For example, one or more of the procedures described above may be embodied by computer program instructions. In this regard, the computer program instructions which embody the procedures described above may be stored by a memory device of an apparatus employing an embodiment of the present invention and executed by a processor in the apparatus. As will be appreciated, any such computer program instructions may be loaded onto a computer or other programmable apparatus (e.g., hardware) to produce a machine, such that the resulting computer or other programmable apparatus embody means for implementing the functions specified in the flowchart block(s) or step(s). These computer program instructions may also be stored in a computer-readable storage memory (as opposed to a computer-readable transmission medium such as a carrier wave or electromagnetic signal) that may direct a computer or other programmable apparatus to function in a particular manner, such that the instructions stored in the computer-readable memory produce an article of manufacture the execution of which implements the function specified in the flowchart block(s) or step(s). The computer program instructions may also be loaded onto a computer or other programmable apparatus to cause a series of operational steps to be performed on the computer or other programmable apparatus to produce a computer-implemented process such that the instructions which execute on the computer or other programmable apparatus provide steps for implementing the functions specified in the flowchart block(s) or step(s).

Accordingly, blocks or steps of the flowchart support combinations of means for performing the specified functions, combinations of steps for performing the specified functions and program instruction means for performing the specified functions. It will also be understood that one or more blocks or steps of the flowchart, and combinations of blocks or steps in the flowchart, can be implemented by special purpose hardware-based computer systems which perform the specified functions or steps, or combinations of special purpose hardware and computer instructions.

In this regard, one embodiment of a method for providing frequency error estimation according to an exemplary embodiment, as shown in FIG. 3 includes receiving, at a receiving station, data descriptive of a received signal provided from a transmitting station at operation 100 and receiving confirmation data descriptive of a signal transmitted by the transmitting station corresponding to the received signal at operation 110. The method may further include performing an error characteristic estimation associated with operation of the receiving station at operation 120. The error characteristic may define a probabilistic value of the error characteristic given the received signal and the corresponding confirmation data.

In some embodiments, the method may include additional optional operations, and example of which is shown in dashed lines in FIG. 3. As such, for example, the method may further include adjusting an operational characteristic of the receiving station to compensate for the error characteristic at operation 130.

In some embodiments, certain ones of the operations above may be modified or further amplified as described below. Modifications or amplifications to the operations above may be performed in any order and in any combination. In this regard, for example, performing the error characteristic estimation may include determining a probabilistic value of a frequency error of the receiving station given the received signal and the corresponding confirmation data. Alternatively, performing the error characteristic estimation comprises determining a probabilistic value of a timing difference of the receiving station given the received signal and the corresponding confirmation data. In some cases, receiving confirmation data may include receiving confirmation of the signal transmitted in a cyclic redundancy check. In an exemplary embodiment, performing the error characteristic estimation comprises performing frequency error estimation based on a non-blind detection as described in greater detail above.

In an exemplary embodiment, an apparatus for performing the method of FIG. 3 above may comprise one or more processors (e.g., the processor 70) configured to perform some or each of the operations (100-130) described above. The processor may, for example, be configured to perform the operations (100-130) by performing hardware implemented logical functions, executing stored instructions, or executing algorithms for performing each of the operations. Alternatively, the apparatus may comprise means for performing each of the operations described above. In this regard, according to an example embodiment, examples of means for performing operations 100-130 may comprise, for example, the processor 70, respective ones of the error determiner 80, the compensator 82, and/or a device or circuit for executing instructions or executing an algorithm for processing information as described above.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. An apparatus comprising at least one processor and at least one memory including computer program code, the at least one memory and the computer program code configured to, with the processor, cause the apparatus to at least perform:
receiving, at a receiving station, data descriptive of a received signal provided from a transmitting station;
receiving confirmation data descriptive of a signal transmitted by the transmitting station corresponding to the received signal; and
performing an error characteristic determination associated with operation of the receiving station, the error characteristic defining a probabilistic value of the error characteristic given the received signal and the corresponding confirmation data.

2. The apparatus of claim 1, wherein the program code causes the apparatus to perform the error characteristic estimation by determining a probabilistic value of a frequency error of the receiving station given the received signal and the corresponding confirmation data.

3. The apparatus of claim 1, wherein the program code causes the apparatus to perform the error characteristic estimation by determining a probabilistic value of a timing difference of the receiving station given the received signal and the corresponding confirmation data.

4. The apparatus of claim 1, wherein the program code causes the apparatus to receive the confirmation data by receiving confirmation of the signal transmitted in a cyclic redundancy check.

5. The apparatus of claim 1, wherein the program code further causes the apparatus to adjust an operational characteristic of the receiving station to compensate for the error characteristic.

6. The apparatus of claim 1, wherein the program code causes the apparatus to perform the error characteristic estimation by performing frequency error estimation based on a non-blind detection.

7. The apparatus of claim 1, wherein the apparatus is a mobile terminal.

8. The apparatus of claim 1, wherein the transmitting station is a base station.

9. A method comprising:
receiving, at a receiving station, data descriptive of a received signal provided from a transmitting station;
receiving confirmation data descriptive of a signal transmitted by the transmitting station corresponding to the received signal; and
performing an error characteristic estimation associated with operation of the receiving station, the error characteristic defining a probabilistic value of the error characteristic given the received signal and the corresponding confirmation data.

10. The method of claim 9, wherein performing the error characteristic estimation comprises determining a probabilistic value of a frequency error of the receiving station given the received signal and the corresponding confirmation data.

11. The method of claim 9, wherein performing the error characteristic estimation comprises determining a probabilistic value of a timing difference of the receiving station given the received signal and the corresponding confirmation data.

12. The method of claim 9, wherein receiving confirmation data comprises receiving confirmation of the signal transmitted in a cyclic redundancy check.

13. The method of claim 9, further comprising adjusting an operational characteristic of the receiving station to compensate for the error characteristic.

14. The method of claim 9, wherein performing the error characteristic estimation comprises performing frequency error estimation based on a non-blind detection.

15. A computer program product comprising a computer-readable storage medium bearing computer program code embodied therein for use with a computer, the computer program code comprising:
code for receiving, at a receiving station, data descriptive of a received signal provided from a transmitting station;
code for receiving confirmation data descriptive of a signal transmitted by the transmitting station corresponding to the received signal; and
code for performing an error characteristic estimation associated with operation of the receiving station, the error characteristic defining a probabilistic value of the error characteristic given the received signal and the corresponding confirmation data.

16. The computer program product of claim 15, wherein code for performing the error characteristic estimation includes instructions for determining a probabilistic value of a frequency error of the receiving station given the received signal and the corresponding confirmation data.

17. The computer program product of claim 15, wherein code for performing the error characteristic estimation includes instructions for determining a probabilistic value of a timing difference of the receiving station given the received signal and the corresponding confirmation data.

18. The computer program product of claim 15, wherein code for receiving confirmation data includes instructions for receiving confirmation of the signal transmitted in a cyclic redundancy check.

19. The computer program product of claim 15, further comprising code for adjusting an operational characteristic of the receiving station to compensate for the error characteristic.

20. The computer program product of claim 15, wherein code for performing the error characteristic estimation includes instructions for performing frequency error estimation based on a non-blind detection.
